(19) United States
(12) Patent Application Publication
(10) Pub. No.: US 2015/0111032 A1
(43) Pub. Date: Apr. 23, 2015

(54) Film, Sheet Substrate for Processing Workpiece, and Sheet for Processing Workpiece

(71) Applicant: LINTEC CORPORATION, Tokyo (JP)

(72) Inventor: Hironobu Fujimoto, Tokyo (JP)

(73) Assignee: LINTEC CORPORATION, Tokyo (JP)

(21) Appl. No.: 14/386,450

(22) PCT Filed: Mar. 19, 2013
(86) PCT No.: PCT/JP2013/057865

§ 371 Date: Jan. 5, 2015

(30) Foreign Application Priority Data
Mar. 23, 2012 (JP) 2012-068000

(51) Int. Cl. C08J 5/18; H01L 21/683

(52) U.S. Cl. CPC C08J 5/18; H01L 21/6836; C08J 2351/00
USPC 428/345; 525/288

(57) ABSTRACT

A film is obtained by forming a film of and curing an energy ray-curable composition comprising a polymerizable silicone compound and an energy ray-curable resin having a viscosity at 25° C. of 100-5,000,000 mPa·S.

### TECHNICAL FIELD

The present invention relates to a film suitably used as a base film of a sheet for the workpiece processing to which said workpiece is adhered and held when carrying out a temporary surface protection, polishing, dicing or so of the workpiece such as the semiconductor or so. Also, the present invention relates to the base film for the workpiece processing including said film, and a sheet for the workpiece processing comprising said base film.

### DESCRIPTION OF THE RELATED ART

A semiconductor wafer such as silicon and gallium arsenide or so are produced to have a larger diameter. The semiconductor wafer is formed with the circuit on the surface and ground to a predetermined thickness, followed by cutting and separating (dicing) into small pieces (semiconductor chip), then it is transferred to the bonding step. During these steps, various adhesive sheet or film form adhesive agents are used.

During the backside grinding, the adhesive sheet so called backside grind sheet is used in order to hold the wafer during the grinding, and also to protect the circuit surface from the grinding debris. Also, following the backside grinding step, in some case, the circuit is formed to the ground face, and the wafer is protected and fixed by the adhesive sheet when carrying out the processing. The surface protection sheet during the backside processing such as the backside grind sheet or so comprises the base film and the adhesive agent layer having a pressure sensitive property. Particularly, in order to securely protect the circuit face having the uneven heights on the surface, the adhesive sheet using the base film relatively soft and with high stress relieving property may be used.

Also, the adhesive sheet used in the dicing step is also called as the dicing sheet, which comprises the base film and the adhesive agent layer having the pressure sensitive adhesive property, and it is used to fix the workpiece when dicing the workpiece such as the semiconductor wafer or so, further it is used to hold the chip after dicing. After the dicing, the adhesive sheet which is relatively soft may be used in order to make the expanding easier which is to separate the chips.

After completing the dicing step, the pickup of the chip is carried out then the die bonding is carried out. At this time, the liquid form the adhesive agent may be used, however recently the film form adhesive agent is widely used. The film form adhesive agent is adhered to one of the face of the semiconductor wafer, and cut together with the wafer during the dicing step; then it is picked up as chip with the adhesive agent layer, and the chip is adhered to a predetermined part via the adhesive agent layer. By producing the membrane of the adhesive agent such as epoxy or polyimide or so on the base film or the adhesive sheet, then making the semi-solidified layer; thereby such film form adhesive agent can be obtained.

Further, the dicing-die bonding sheet is also proposed which has both the wafer fixing function during the dicing step, and the die bonding function during the die bonding. Dicing die bonding sheet comprises the adhesive resin layer having both the wafer holding function and the die bonding function, and the base film. The adhesive resin layer holds the semiconductor wafer or chip during the dicing step, and functions as the adhesive agent for adhering the chip during the die bonding. The adhesive resin layer is cut together with the wafer at the dicing, and the adhesive resin layer having the same shape as the cut chip is formed. After completing the dicing, once the pickup of the chip is carried out, the adhesive resin layer is released from the base film together with the chip. The chip with the adhesive resin layer is mounted on the base film, and the heating or so is carried out, thereby the chip and the base film are adhered via the adhesive resin layer. Such dicing-die bonding sheet is formed by having the adhesive resin layer having both of the wafer fixing function and the die bonding function, on the base film.

Even for the adhesive sheets for these die bonding, in order to make the expanding step easier, a relatively soft base film can be used.

Also, in order to form the protection film on the backside of the chip, a process of producing the chip having the cured resin layer (the protection film) is proposed wherein the semiconductor wafer is adhered to the curable resin layer, and the resin layer is cured, then dicing the semiconductor wafer and the resin. Such sheet for forming the protection film comprises the adhesive resin layer which becomes the protection film on the releasable base film. For the sheets used in such steps, as for the base film for holding the resin layer, a relatively soft base film may be used in order to comply with the expanding step.

Hereinafter, the above mentioned surface protection sheet, a backside grinding sheet, a dicing sheet, a multilayered sheet including the film form adhesive agent layer, a dicing-die bonding sheet, a protection film forming sheet will all be called as “a sheet for workpiece processing”. Also, the adhesive agent layer or the film form adhesive agent layer having the pressure sensitive adhesiveness, the adhesive resin layer having both the wafer holding function, and the adhesive resin layer which becomes the protection film may be simply called as “the adhesive resin layer”.

As for such sheet for workpiece processing, conventionally, vinyl chloride or polyolefin film or so are used as the base film; however recently, particularly in order to securely protect the circuit surface having the uneven heights on the surface, and also in order to correspond to the expanding step, the adhesive sheet using the base film which is relatively soft and with high stress relieving property is in demand. As such sheet for the workpiece processing, various resin films used as soft base film are proposed. For example, the patent article 1 (JP Patent No. 3383227) proposes the backside grinding sheet having the base film using the film formed by curing a membrane comprising the energy ray curable resin such as urethane acrylate oligomer or so; the patent article 2 (JP Patent Application No. 2002-141306) proposes the dicing having the base film using the film formed by curing a membrane comprising the energy ray curable resin such as urethane acrylate oligomer or so. These base films are soft, and has excellent stress relieving property, thus it has been considered for the surface protection of the semiconductor wafer having a uneven heights on the surface, and also as the base film of various sheet for the workpiece processing.

### PRIOR ART

### Patent Article

[Patent Article 1] Japanese Patent No. 3383227
[Patent Article 2] Japanese Patent Application Laid Open No. 2002-141306

### DISCLOSURE OF INVENTION

### Problem to be Solved by the Invention

However, the film as described in the patent article 1 and the patent article 2 or so wherein the energy ray curable resin such as urethanacrylate oligomer or so is casted and cured, in many cases it had weak tuck property (the weak adhesiveness) at the surface, and the coefficient of the static friction is high. Therefore, after mounting the sheet for the workpiece processing on the table for the processing, the sheet adheres to the table; hence it may cause a trouble during the moving step which is subsequent steps. Also, there may be a chance that a blocking of the film may occur, and the sheet may adhere to the rolls for moving the sheet, thus the production of the sheet or the move may be interfered.

In order to solve such problems, in general, as for the method to decrease the coefficient of the static friction of the film; the method of forming the resin layer having low coefficient of the static friction as the top coat layer on the surface of the film which becomes the base film; or the method of adding the lubricant such as silicone oil or so are known. However, since the step for forming the top coat layer is added, this causes to increase the product price. Also, the thickness of the top coat layer is as thin as 2 to 3 μm, thus the pin hole may be generated when coating the resin which forms the top coat layer, unevenness of the coating may take place, or it may be difficult to maintain the uniformity of the quality.

Also, the silicone oil used as the lubricant may segregated on the film surface, and there is a chance of causing the bleed out or so, which may cause a serious problem such as the contamination of the workpiece, or the variation of the film physical properties or so.

The present invention is achieved in view of such circumstances, and the object is to provide the base film having high stress relieving property and the expand property, with no workpiece contamination; and further having reduced tuck property of the surface. Such film has high aptitude as the base film for various sheet of the workpiece for the processing, further as there is no need to form the top coat layer, the production steps can be simple and the production cost can be reduced as well.

### Means for Solving the Problems

The present invention includes following gist in order to solve the above mentioned problems.

(1) A film made by curing a membrane comprising an energy ray curable composition including an energy ray curable resin having a viscosity at 25° C. of 100 to 5,000,000 mPa·S, and a polymerizable silicone compound.

(2) The film as set forth in (1), wherein a weight ratio of said polymerizable silicone compound is 1.0 wt % or less.

(3) The film as set forth in (1), wherein said polymerizable silicone compound is an organic modified polymerizable silicone compound.

(4) The film as set forth in (3), wherein said organic modified polymerizable silicone compound is urethane modified silicone (meth)acrylate or urethane modified silicone (meth)acrylate oligomer.

(5) The film as set forth in any one of (1) to (4), wherein said energy ray curable resin is a mixture of urethane acrylate based oligomer and energy ray polymerizable monomer.

(6) A base film to be used for a sheet for workpiece processing comprising the film as set forth in any one of (1) to (5).

(7) A sheet for workpiece processing comprising the base film of (6) and an adhesive resin layer on at least one side of said base film.

(8) The sheet for workpiece processing as set forth in (7), wherein said adhesive resin layer is an adhesive layer having a pressure sensitive adhesiveness.

(9) The sheet for workpiece processing as set forth in (7), wherein said adhesive resin layer is an adhesive layer having a pressure sensitive adhesiveness and die bonding function.

### The Effect of the Invention

According to the present invention, the film having high stress relieving property or the expand property, but without workpiece contamination, and further with reduced surface tuck property can be obtained. This film is excellent in the above mentioned properties, hence it is highly suitable as the base film for various sheet for workpiece processing, and also as there is no need of forming the top coat layer, it is possible to make the production steps simple, and the production cost can be reduced.

### BRIEF DESCRIPTION OF THE DRAWINGS

FIG. 1 is a cross section of the sheet for the workpiece processing according to one embodiment of the present invention.

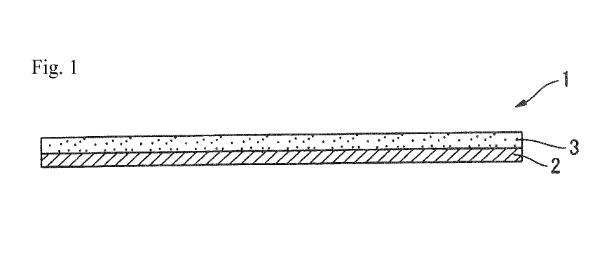

### THE EMBODIMENTS FOR CARRYING OUT THE INVENTION

Hereinbelow, the embodiment of the film, the base film to be used for a sheet for the work piece processing including said film, and the sheet for the workpiece processing comprising the base film according to the present invention will be explained based on the attached FIGURE.

The film according to the present invention can be obtained by curing a membrane comprising the energy ray curable composition including the energy ray curable resin and the polymerizable silicone compound.

### (The Energy Ray Curable Resin)

The energy ray curable resin has a viscosity at 23° C. of 100 to 5,000,000 mPa·s, preferably 300 to 2,000,000 mPa·s, further preferably 500 to 1,000,000 mPa·s. Also the viscosity at 60° C. is preferably 100 to 200,000 mPa·s, further preferably 300 to 100,000 mPa·s. When the viscosity is too low, the coating of the thick membrane becomes difficult, and the film having a desired thickness may not be obtained. Also, in case the viscosity is too low, the coating itself may become difficult.

The energy ray curable resin has a property which cures once it receives the energy ray irradiation. Therefore, after the membrane production of the energy ray curable resin having appropriate viscosity, and the energy ray irradiation is carried out, the cured film is obtained.

As for the energy ray curable resin, for example, urethane acrylate based oligomer, energy ray curable monomer, epoxy modified acrylate, telechelic polymer and the mixtures thereof can be used. Among these, the mixture of urethane acrylate based oligomer and the energy ray polymerizable monomer are particularly preferably used as it is easy to regulate the viscosity and the reactivity, and has high stress relieving property and the expand property of the obtained cured product.

Urethane acrylate based oligomer is obtained by reacting terminal isocyanate urethane prepolymer obtained by reacting polyvalent isocyanate compound and polyol compounds such as polyether type, polyester type, or polycarbonate type or so, with (meth)acrylate having hydroxyl group. Also, (meth)acrylate is used in terms of acrylate and methacrylate both.

The polyol compound may be any of polyether type polyol, polyester type polyol, or polycarbonate type polyol; however better effect can be obtained by using polycarbonate type polyol. Also, it is not particularly limited, as long as it is polyol, and it may be difunctional diol, trifunctional triol or so. However, from the point of easiness to obtain, a general purpose use, and a reactivity, diol is particularly preferably used. Therefore, as for the polyol compound, diols such as polyether type diol, polyester type diol, polycarbonate type diol or so are preferably used.

Polyether type diol is in general expressed by HO—(—R1-O)n-H. Here, R1 is alkylene group, preferably alkylene group having the carbon atoms of 1 to 6, and particularly preferably alkylene group having the carbon atoms of 2 or 3. Also, among alkylene groups having the carbon atoms of 1 to 6, preferably ethylene, propylene, butylene or tetramethylene are preferable, and ethylene or propylene are particularly preferable. Also, n is preferably 2 to 200, further preferably 10 to 100.

Specifically, as polyether type diol, polyethylene glycol, polypropylene glycol, polybutylene glycol, polytetramethylene glycol or so may be mentioned. Further, as particularly preferable polyether type diol, polyethylene glycol, polypropylene glycol or so may be mentioned.

By reaction between polyvalent isocyanate compound below described, polyether type diol generates terminal isocyanate urethane prepolymer introduced with ether bond part (—(—R1-O—)n-). Such ether bond part may be a structure lead by the open ring reaction of cyclic ether such as ethylene oxide, propylene oxide, tetrahydrofurane or so.

Polyester type diol is those obtained by the condensation reaction between polybasic acid and glycols.

As the poly basic acid, the known polybasic acid such as phthalic acid, adipic acid, phthalic acid anhydride, isophthalic acid, terephthalic acid, tetrahydrophthalic anhydride, cis-1,2-dicarboxylic acid anhydride, dimethyl terephthalic acid, monochloro phthalic acid, dichlorophthalic acid, trichlorophthalic acid, tetrabromophthalic acid or so can be used. Among these, preferably, phthalic acid, adipic acid, phthalic acid anhydride, isophthalic acid, terephthalic acid, tetrahydrophthalic acid anhydride, dimethylterephthalic acid; and particularly preferably it is phthalic acid, adipic acid, phthalic acid anhydride, isophthalic acid, terephthalic acid or so.

As glycols, it is not particularly limited, and for example, ethylene glycol, diethylene glycol, propylene glycol, 1,4-butane diol, 1,5-pentane diol, neopentyl glycol, 1,6-hexane diol or so may be mentioned.

As for other polyester type diol, polylactone diols or so which is obtained by the ring opening polymerization of aforementioned glycols and ε-caprolactone may be mentioned.

Polycarbonate type diol is expressed in general by HO—(—R—O—C(═O)—O)n-R—OH. Here, R is divalent hydrocarbon which may be same or different, and preferably it is alkylene group, particularly preferably it is alkylene group having the carbon atoms of 2 to 100, particularly preferably it is a alkylene group having the carbon atoms of 2 to 12. Also, among the alkylene groups, preferably it is ethylene, propylene, butylene, tetramethylene, pentamethylene, hexamethylene or so, and particularly preferably it is pentamethylene, hexamethylene or so. Also, n is preferably 1 to 200, and more preferably 1 to 100.

Specifically, as carbonate type diol, 1,4-teramethylene carbonate diol, 1,5-pentamethylene carbonate diol, 1,6-hexamethylene carbonate diol, 1,2-propylene carbonate diol, 1,3-propylene carbonate diol, 2,2-dimethyl propylene carbonate diol, 1,7-heptamethylene carbonate diol, 1,8-octamethylene carbonate diol, 1,9-nonane methylene carbonate diol, 1,4-cyclohexane carbonate diol or so.

Diols may be used alone, or by combining two or more thereof. The above mentioned diols generates terminal isocyanate urethane prepolymer by reaction between polyvalent isocyanate compound.

As the polyvalent isocyanate compound, for example, 4,4′-dicyclohexylmethane diisocyanate, isophorone diisocyanate, 2,4-tolyene diisocyanate, 2,6-tolyene diisocyanate, 1,3-xylene diisocyanate, 1,4-xylene diisocyanate, diphenyl methane-4,4′-diisocyanate or so are used, and particularly preferably, 4,4′-dicyclohexyl methane diisocyanate, hexamethylene diisocyanate, tetramethylene diisocyanate, trimethylhexamethylene diisocyanate, norbornane diisocyanate, dicyclohexyl methane-2,4′-diisocyanate or so are used.

Next, urethane acrylate based oligomer can be obtained by reacting the above mentioned diols, (meth)acrylate having hydroxyl group, and terminal isocyanate urethane prepolymer obtained by the reaction between the above mentioned polyvalent isocyanate compound. As for (meth)acrylate having the hydroxyl group, it is not particularly limited as long as it is a compound having the hydroxyl group and (meth)acryoyl group in one molecule. For example, hydroxyl alkyl (meth)acrylate such as 2-hydroxyethyl (meth)acrylate, 2-hydroxypropyl (meth)acrylate, 2-hydroxybutyl (meth)acrylate, 4-hydroxycyclohexyl (meth)acrylate, 5-hydroxycyclooctyl (meth)acrylate, 2-hydroxy-3-phenyloxypropyl (meth)acrylate, pentaerythritol tri(meth)acrylate or so; polyethylene glycol (meth)acrylate, polypropylene glycol (meth)acrylate or so can be used.

Urethane acrylate based oligomer is expressed by the general formula: Z—(Y—(X—Y)m)-Z (here, X is a constitutional unit derived from diols, Y is a constitutional unit derived from the polyvalent isocyanate compound, and Z is a constitutional unit derived from (meth)acrylate having the hydroxyl group). “m” in the above mentioned general formula, it is selected so that it becomes preferably to 1 to 200, and more preferably to 1 to 50.

The obtained urethane acrylate based oligomer has photopolymerizable double bond in the molecule, and it polymerize cures by the energy ray irradiation, thereby it has a property to form the coating.

The weight average molecular weight of urethane acrylate based oligomer preferably used in the present invention is 1000 to 50000, and more preferably 2000 to 40000. The above mentioned urethane acrylate based oligomer may be used alone or by combining two or more thereof

However, in case of using urethane acrylate based oligomer as mentioned in the above alone, the membrane production may become difficult, thus in the present invention, it is preferable to use together with the energy ray curable monomer to regulate the viscosity. The energy ray curable monomer has energy ray polymerizable double bond in the molecule, and particularly in the present invention, acrylate based compound having relatively bulky group is preferably used.

As the specific example of the energy ray curable monomer, alicyclic compounds such as isobornyl (meth)acrylate, dicyclopentenyl (meth)acrylate, dicyclopentanyl (meth)acrylate, dicyclopentenyl (meth)acrylate, cyclohexyl (meth)acrylate, adamantine (meth)acrylate, tricyclodecane acrylate or so; aromatic compounds such as phenylhydroxypropyl acrylate, benzyl acrylate, phenolethyleneoxide modified acrylate or so; heterocyclic compounds such as tetrahydrofurfuryl (meth)acrylate, morpholine acrylate, N-vinylpyrrolidone or N-vinylcaplolactam or so may be mentioned. Also, depending on the needs, polyfunctional (meth)acrylate may be used. Such energy ray curable monomer may be used alone or by combining two or more thereof

The above mentioned energy ray curable monomer is used in the ratio of preferably 5 to 900 parts by weight, more preferably 10 to 500 parts by weight, and particularly preferably 30 to 200 parts by weight with respect to 100 parts by weight of urethane acrylate based oligomer. The energy ray curable resin preferably includes urethane acrylate based oligomer and energy ray curable monomer.

Also, the energy ray curable resin may use the aforementioned epoxy modified acrylate, telechelic polymer or so besides the above mentioned urethane acrylate based oligomer and energy ray curable monomer.

As epoxy modified acrylate, bisphenol A modified epoxy acrylate, glycol modified epoxy acrylate, propylene modified epoxy acrylate, phthalic acid modified epoxy acrylate or so may be mentioned.

Telechelic polymer is a polymer having a group with polymerizable double bond such as (meth)acryloyl group or so at the both ends of the molecule, and silicone type telechelic acrylate, urethane type telechelic acrylate or so may be mentioned.

The energy ray curable resin generates the cured product such as film or so by undergoing the polymerization and curing by the energy ray irradiation. By blending the photopolymerization initiator when carrying out the energy ray irradiation, the time for the polymerize curing by the energy ray irradiation and the energy ray irradiation amount can be reduced. As for such photopolymerization initiator, a photopolymerization initiator such as benzoin compound, acetophenone compound, acylphosphinoxide compound, titanocene compound, thioxanthone compound, peroxide compound or so, a photosensitizer such as amine or quinone or so may be mentioned; and specifically 1-hydroxycyclohexylphenyl ketone, 2-hydroxy-2-methyl-1-phenylpropane-1-one, benzoin, benzoin methylether, benzoin ethylether, benzoin isopropylether, benzyldiphenyl sulfide, tetramethylthiuram monosulfide, azobisisobutylonitrile, dibenzyl, diacetyl, β-chloranthraquinone or so may be mentioned.

The used amount of the photopolymerization initiator is preferably 0.05 to 15 parts by weight, more preferably 0.1 to 10 parts by weight, and particularly preferably 0.3 to 5 parts by weight with respect to 100 parts by weight of the energy ray curable resin.

The energy ray curable resin is constituted from various polymers, oligomers, monomers having the energy ray curable property as mentioned in the above, and the photopolymerzation initiator; and the component ratio is regulated so that the viscosity at 23° C. is 100 to 5,000,000 mPa·s. The viscosity of the energy ray curable resin decreases as the amount of the low molecular weight compound increases, and it tends to increase as the amount of the large molecular weight compound increases, hence the viscosity can be regulated depending of the blending ratio of various component.

The energy ray curable resin does not necessarily have to include solvents or so, however small amount of solvent may be included to regulate the viscosity. In case the energy ray curable resin includes the solvent, the step of removing the solvent will be necessary after the coating of the energy ray curable composition. Therefore, the solvent used for the viscosity regulation is small amount, and it may be included in the ratio of less than 70 parts by weight with respect of 100 parts by weight of the energy ray curable resin.

### (The Polymerizable Silicone Compound)

The energy ray curable composition includes the above mentioned energy ray curable resin and the polymerizable silicone compound.

The polymerizable silicone compound is a compound having main backbone of siloxane bond (the silicone backbone) and the polymerizable group in the molecule.

The polymerizable group is a group capable of polymerizing with the above mentioned energy ray curable resin, and the group comprising the polymerizable double bond such as (meth)acryloyl group, (meth)acryloyloxy group or so may be mentioned. Preferably, it is (meth)acryloyl group. Here, (meth)acryloyl group refers to both of acryloyl group and methacryloyl group.

Therefore, the preferable polymerizable silicone compound is preferably silicone (meth)acrylate or silicone (meth)acrylate oligomer (hereinafter, it will be referred as “silicone (meth)acrylate”). Here, (meth)acrylate is used in terms of acrylate and methacrylate both.

Also, from the point of improving the compatibility between the aforementioned energy ray curable resin, the polymerizable silicone compound is preferably an organic modified polymerizable compound comprising a part which improves the compatibility with said energy ray curable resin in the molecule. As for such organic modified polymerizable silicone compound, for example the silicone compounds of urethane modified, amino modified, alkyl modified, epoxy modified, carboxyl modified, alcohol modified, fluorine modified, alkylaralkylpolyether modified, epoxypolyether modified or polyether modified or so may be mentioned.

For example, in case the energy ray curable resin includes urethane acrylate based oligomer, the polymerizable silicone compound is preferably urethane modified silicone (meth)acrylate.

Urethane modified silicone (meth)acrylate is obtained by reacting the silicone compound of which the both ends are OH with said polyvalent isocyanate to obtain terminal isocyanate silicone compound, and then reacting the terminal isocyanate silicone compound with said hydroxyl group containing (meth)acrylate.

Also, the polymerizable group included in the polymerizable silicone compound is preferably 1 to 6 per one molecule, more preferably it is 2 or less, and particularly preferably 1 or less from the point that the crosslinking structure of the cured product will be highly densed and to suppress the stress relieving property and expanding property to decline. Such polymerizable silicone compound may be used alone or by mixing two or more thereof

As for these, those already known or commercially available one can be used, and as the commercially available products, product name of “EBECRYL1360”, “EBECRYL350”, “KRM8495” made by DAICEL-ALLNEX LTD, and product name of “CN9800”, “CN990” or so made by ARKEMA K.K. or so may be mentioned.

The polymerizable silicone compound comprises the polymerizable group which has curable property by the energy ray irradiation, therefore it is possible to polymerize with the energy ray curable resin in the energy ray curable composition. That is, the composition including the above mentioned energy ray curable resin and the polymerizable silicone compound are casted and dried to fix the silicone structure in the film, thereby the film without the segregation of the silicone compound in the film surface and the bleed out or so can be obtained. Particularly, by using urethane acrylate based polymer as the energy ray curable resin, and using the polymerizable silicone compound having the urethane bonding part as the polymerizable silicone compound, the energy ray curable composition having high compatibility and stable liquid physical property over the time can be obtained.

### (The Energy Ray Curable Composition)

The energy ray curable resin composition includes the above mentioned energy ray curable resin and the polymerizable silicone compound, and by curing a membrane comprising said energy ray curable resin composition, the film can be obtained.

The film obtained by curing a membrane comprising the energy ray curable composition hardly has the blocking or so and has excellent processing aptitude since the surface tuck property is suppressed due to the silicone structure. Also, particularly, in case of using urethane acrylate based oligomer, the stress relieving property and the expanding property of the film are high, thus it is preferably used when processing various workpieces.

In order to achieve the object of suppressing the surface tuck property of the film, it is thought to be preferable as more silicone structure is in the film surface. However, as the blending amount of the polymerizable silicone compound increases, the unreacted silicone compound also increases, and the unreacted silicone compound may adhere to the workpiece or the processing table. Therefore, the blending amount of the polymerizable silicone compound in the energy ray curable composition is usually 10 wt % or less, and preferably 1 wt % or less. The polymerizable silicone compound exhibits significant effect to suppress the surface tuck property just by adding a small amount. Therefore, the blending amount of the polymerizable silicone compound in the energy ray curable composition is sufficient if it is 0.01 wt % or more; and in order to enhance the effect of suppressing the surface tuck property, it is further preferably to be 0.2 wt % or more, and particularly preferably 0.5 wt % or more.

Also, in the energy ray curable composition, inorganic filler such as calcium carbonate, silica, and mica or so; metal filler such as iron and lead or so; antistatic agent, antioxidant, and organic lubricants or so may be added. Further, besides the above mentioned components, additives such as coloring agents such as pigments and dye or so may be comprised in the energy ray curable composition.

### <The Film>

The film according to the present invention is made by curing a membrane comprising the above mentioned energy ray curable composition. This film has suppressed surface tuck property, thus the blocking of the film causing the sheet to adhere to the rolls for move the sheet does not occur, and hence the production of the sheet and the moving is not interfered. Also, the film of the present invention comprises a mechanical strength which allows to be used as the self-supporting film; and it have excellent expanding property and the stress relieving property, thus it is particularly preferably used as the base film of various sheets for worksheet processing such as backside grinding sheet or the dicing sheet or so.

Also, the thickness of the film of the present invention is preferably 10 to 500 μm, further 30 to 300 μm and particularly preferably 50 to 200 μm.

As the method of the production of the film, it is not particularly limited, and known methods can be used. The method so called as the flow casting (casting) can be preferably employed. Specifically, after casting the energy ray curable composition into a thin film form on the casting sheet of PET or so, the energy ray such as the ultraviolet ray and electron beam or so is irradiated to the casted film to polymerize cure, then it is made into a film by releasing the casting sheet. According to such production method, the stress applied to the resin during the membrane production can be made small, and has only little formation of the fish eye. Also, the uniformity of the film thickness is high, and the accuracy of the thickness is usually within 2%.

The obtained film has a silicone structure dispersed uniformly in the film, and by fixing the silicone structure, the surface tuck property is suppressed, further the silicone compound does not segregate to the film surface and the bleed out does not occur as well. Specifically, the coefficient of the static friction at the film surface of the side contacting the casting sheet is preferably 1.0 or less. Therefore, even if the sheet for workpiece processing using said film as the base film is mounted on various processing table then taken off, the sheet does not adhere to the processing table, and the move to the next step can be carried out smoothly.

Also, as the silicone structure is fixed in the film, the transfer of the silicone compound to other members is reduced. Thereby, the contamination of the workpiece or the variation of the film physical property can be suppressed. Specifically, in case the casting sheet is released after the above mentioned casting, Si element ratio in the casting sheet surface becomes the index of the bleed out amount of the silicone compound to the base film surface, and it is usually 1% or less. Note that, here, Si element ratio refers to the weight ratio of Si element with respect to the total element adhered, by measuring the amount of elements of carbon, oxygen, nitrogen, and silicon which has adhered onto the casting sheet.

### <The Base Film to be Used for a Sheet for Workpiece Processing>

The base film to be used for a sheet for the workpiece processing of the present invention (hereinafter it may be simply referred as “base film”) includes the film of the present invention as mentioned in the above. Said base film may be a single film layer of the above mentioned present invention, and it may be a multilayered product of the film of the present invention. Also, said base film may be a multilayered film of the above mentioned film of the present invention, and other film such as polyolefin film, polyvinylchloride film, polyethylene terephthalate film or so. Among these, as it is easy to obtain the effect of the present invention, the base film to be used for a sheet for the film workpiece processing is preferably the single layer film of the above mentioned present invention.

Note that, in the present invention, the sheet for the workpiece processing is a general name for the surface protection sheet, the backside grinding sheet, the dicing sheet, the multilayered sheet including a film form adhesive agent, dicing-die bonding sheet and the protection film forming sheet or so, to which the workpiece is adhered and held when carrying out the processing such as temporary surface protection, the polishing, and the dicing or so of the workpiece such as the semiconductor wafer or so.

Also, in case at least one face of the base film has the adhesive resin layer, which will be described in the following, at the face contacting with the adhesive resin layer of the base film, a corona treatment may be carried out or other layer such as primer or so may be provided in order to improve the adhesiveness between the adhesive resin layer. Further, in case of transferring the adhesive resin layer to the chip or so after releasing the adhesive resin layer from the base film, in order to make the releasing easier between the adhesive resin layer and the base film, a releasing treatment may be carried out to the base film surface. In this case, the surface tension of the base film is preferably 40 mN/m or less, further preferably 37 mN/m or less, and particularly preferably 35 mN/m or less. As the releasing agent used for the releasing treatment, alkyd based, silicone based, fluorine based, unsaturated polyester based, polyolefin based, wax based or so may be used; however the releasing agent having the heat resistance is preferable such as alkyd based, silicone based, fluorine based or so.

In order to carry out the releasing treatment to the surface of the base sheet using the above releasing agent, the releasing agent is coated as it is which means no solvent is included, or under the condition being diluted by the solvent or emulsified condition, using the gravure coater, the Mayer bar coater, the air knife bar coater, roll coater or so. Then it is cured by setting to the room temperature, applying the heat, or by electron beam or so, the multilayer body may be formed by a wet lamination or dry lamination, a heat melting lamination, a melt extrusion lamination, a coextrusion process or so.

The base film to be used for a sheet for the workpiece processing of the present invention is suitably used as the base film of the surface protection sheet, specifically as the base film of the surface protection sheet which is adhered to the circuit face of the semiconductor wafer formed with the circuit on the surface during the backside grinding of the wafer, and the backside of the wafer is ground while protecting the circuit face to form a wafer having the predetermined thickness. At the circuit surface, the uneven heights derived from the circuit are formed in many cases, and by adhering the surface protection sheet, the uneven heights is embedded thereby the circuit surface is protected from the foreign matter or the grinding water generated during the processing.

In case urethane acrylate based oligomer is used as the constitutional element of the above mentioned base film, since the base film has high stress relieving property, the base film also changes its shape in accordance with the uneven heights of the wafer surface, and the adhesive resin layer is embedded into the wafer face to overcome the uneven heights, thereby the wafer can be held in a flat state. Also, since the base film face has low surface tuck property, after the predetermined step is completed, it can be easily taken off from the grinding table, thus the move to the next step can be done smoothly.

Further, following the above mentioned backside grinding step, various processing may be carried out to the wafer backside. For example to further form the circuit pattern to the wafer backside, a treatment involving the generation of heat such as etching treatment or so may be carried out. Also, die bonding film may be heat pressure adhered to the wafer backside. For these steps, the circuit pattern can also be protected by adhering the sheet for the workpiece processing of the present invention.

Also, the base film to be used for a sheet for the workpiece processing of the present invention is relatively soft and has excellent expanding property, and particularly the chip spaces can be easily widen isotropically, thus it shows excellent chip alignment after the expanding. Hence, it can be suitably used as the base film of the dicing sheet. The dicing sheet fixes the wafer during the dicing, and when the dicing step is done, the chip is picked up. At this time, the chip is picked up by using the penetrating pin or suction collet or so. Also, during the pickup of the chips, in order to separate the space between the chips, it is preferable to expand the dicing sheet while the chip is fixed to the dicing sheet. The space between the chip separates due to the expanding, and it becomes easy to confirm the chip; and also the breakage due to the contact between the chips is reduced and the yield can be improved.

Therefore, the base film of the present invention can be suitably used as the base film of the dicing sheet as it has excellent flexibility and expanding property.

Further, it is also suitable for the use which involves the expanding based on the same reason, for example for the sheet wherein the chip is picked up after the separated chip is transferred to other sheet and expanded.

### <The Sheet for the Workpiece Processing>

The sheet for the workpiece processing of the present invention comprises the adhesive resin layer to at least one face of the above mentioned base film to be used for a sheet for the workpiece processing.

As shown in Table 1, the sheet 1 for the workpiece processing of the present invention comprises the adhesive resin layer 3 to at least one face of the above mentioned base film 2. The adhesive resin layer of the sheet for the workpiece processing is appropriately selected from the resin comprising various functions in accordance with the purpose of the sheet. Also, the adhesive resin layer 3 may be a single layer, or multilayer. Further, the adhesive resin layer 3 may be formed on entire surface of one face of the base film 2, or it may be formed at a part thereof

### (The Adhesive Layer)

In case of using the sheet for the workpiece processing of the present invention as the surface protection sheet such as the backside grind sheet, or as the dicing sheet, the adhesive resin layer 3 is preferably made from the adhesive agent layer having the pressure sensitive adhesiveness.

The adhesive agent layer having the pressure sensitive adhesiveness as such can be formed from conventionally known various adhesive agents. As the adhesive agent, it is not particularly limited; however for example, the adhesive agent such as rubber based, acrylic based, silicone based, polyvinylether based or so can be used. Among these, the acrylic based adhesive agent which is easy to regulate the adhesive force is particularly preferable.

The acrylic based adhesive agent has (meth)acrylate copolymer as the main component. As (meth)acrylate copolymer, the copolymer between the monomer of one or more of alkyl (meth)acrylate made of alkyl group without the functional group such as methyl acrylate, ethyl acrylate, propyl acrylate, butyl acrylate, 2-ethylhexyl acrylate, decyl acrylate, dodecyl acrylate, lauryl acrylate, myristyl acrylate, methyl methacrylate, ethyl methacrylate, propyl methacrylate, butyl methacrylate, benzyl acrylate, cyclohexyl acrylate, isobornyl acrylate, with depending on needs, one or more monomers selected from the polymerizable monomers such as hydroxyl group containing (meth)acrylate such as 2-hydroxyethyl acrylate, 2-hydroxypropyl acrylate, 3-hydroxypropyl acrylate, 3-hydroxybutyl acrylate, 4-hydroxybutyl acrylate, 2-hydroxyethyl methacrylate, 2-hydroxypropyl methacrylate, 2-hydroxypropyl methacrylate, 3-hydroxypropyl methacrylate, 3-hydroxybutyl methacrylate, 4-hydroxybutyl methacrylate or so; carboxyl group containing compound such as acrylic acid, methacrylic acid, maleic acid, phthalic acid or so; vinyl esters such as vinyl acetate, vinyl propionate or so; cyano group containing compound such as acrylonitrile, methacrylonitrile or so; amide group containing compound such as acrylic amide or so; aromatic carbons such as styrene, vinyl pyridine or so may be mentioned. Note that, when the polymerizable monomer is only one, strictly speaking it is not a copolymer, however it will be called copolymer including such case. Also, (meth)acrylate is used in terms of both of acrylate and (meth)acrylate.

The content ratio of the unit derived from alkyl (meth)acrylate made of alkyl group without the functional group in alkyl (meth)acrylate copolymer is preferably 10 98 wt %, more preferably 20 to 95 wt %, and further preferably 50 to 93 wt %. The weight average molecular weight of (meth)acrylate copolymer is 100,000 to 2,500,000, more preferably 200,000 to 1,500,000, and particularly preferably 300,000 to 1,000,000. Note that, in the present specification, the weight average molecular weight is a polystyrene corresponding value measured by the gel permeation chromatography method.

These adhesive agents can be used alone or by combining two or more thereof. Among these adhesive agents, the acrylic based adhesive agent is preferably used. Particularly, the acrylic based adhesive agents obtained by crosslinking one or more of crosslinking agent such as the acrylic based copolymer with polyisocyanate based crosslinking agent, epoxy based crosslinking agent, aziridine based crosslinking agent, chelate based crosslinking agent or so.

As epoxy based crosslinking agent, (1,3-bis(N,N-diglycidylaminomethyl)cyclohexane, N,N,N′,N′-tetraglycidyl-m-xylenediamine, N,N,N′,N′-tetraglycidylaminophenylmethane, triglycidylisocyanate, m-N,N-diglycidylaminophenylglycidylether, N,N-diglycidyltoluidine, N,N-diglycidylaniline, pentaerythritolpolyglycidylether, 1,6-hexanediolglycidylether or so may be mentioned.

As for polyisocyanate based crosslinking agent, tolylenediisocyanate (TDI), hexamethylenediisocyanate (HMDI), isophoronediisocyanate (IPDI), xylenediisocyanate (XDI), hydrogenated tolylenediisocyanate, diphenylmethanediisocyante and the hydrogenates thereof, polymethylenepolyphenylpolyisocyanate, naftylene-1,5-diisocyanate, polyisocyanate prepolymer, polymethylolpropane modified TDI or so may be mentioned.

The crosslinking agent may be used alone or two or more thereof may be combined. The used amount of the crosslinking agent is 0.01 to 20 parts by weight with respect to 100 parts by weight of acrylic based copolymer.

Further, the adhesive agent layer may be those capable of controlling the adhesive force by the energy ray curing, heat foaming, and water swelling or so. In case the adhesive agent layer comprises the energy ray curable property, the energy ray is irradiated to the adhesive layer, and the adhesive force can be reduced thereby the wafer or chip is easily released. Also, the energy ray curing type adhesive agent layer can be formed by various energy ray curing type adhesive agent which cures by irradiating conventionally known energy ray such as gamma ray, electron beam, ultraviolet ray and visible light or so; however it is particularly preferable to use the ultraviolet ray curing type adhesive agent.

As for the energy ray curing adhesive agent, for example, the adhesive agent mixing the polyfunctional energy ray curing resin to the acrylic based adhesive agent may be mentioned. As the polyfunctional energy ray curing resin, the low molecular weight compound comprising plurality of functional group of energy ray polymerizable type, urethane acrylate oligomer or so may be mentioned. Also, the adhesive agent including the acrylic based copolymer comprising the energy ray polymerizable type functional group at the side chain can be used as well. As for such energy ray polymerizable functional group, (meth)acryloyl group is preferable.

The glass transition temperature (Tg) of the adhesive agent layer is preferably −50° C. to 30° C., and preferably −25° C. to 30° C. Here, Tg of the adhesive agent layer is the temperature which shows the maximum value of loss tangent (tan δ) at the range of −50 to 50° C. in the dynamic elasticity measurement at the frequency 11 Hz of the sample stacked with the adhesive agent layer. Note that, in case the adhesive agent layer is the energy ray curing adhesive agent, it refers to the glass transition temperature before curing the adhesive agent layer by the energy ray irradiation. In case the adhesive agent layer is made of said acrylic based adhesive agent, the glass transition temperature of the adhesive agent layer is regulated by the type and the polymerization ratio of the monomer constituting said acrylic based adhesive agent, and it can be regulated by estimating the influence of the ultraviolet curable compound or the crosslinking agent which is added depending on the case.

### (The Film Form Adhesive Agent)

Also, in the sheet 1 for the workpiece processing of the present invention, the adhesive resin layer 3 may be film form adhesive agent. Such film form adhesive agent is widely used in recent years for the die bonding of the chip. Such film form adhesive agent is preferably those semi-curing (B-stage state) a membrane comprising epoxy based adhesive agent or polyimide based adhesive agent, and formed on the base film to be used for a sheet for the workpiece processing of the present invention in a releasable manner, thereby the sheet 1 for the workpiece processing of the present invention can be obtained. Also, the adhesive agent layer may be formed on one face of the base film 2, and the film form adhesive agent may be stacked on adhesive agent layer.

The film form adhesive agent is adhered to the semiconductor wafer. By dicing the semiconductor and the film formed adhesive agent thereof to a chip size, the chip with the adhesive agent can be obtained, and this is being picked up from the base film or the adhesive sheet, and the chip is fixed to predetermined position via the adhesive agent. Note that, during the pickup of the chip with the adhesive agent, it is preferable to expand as mentioned in above.

### (The Adhesive Agent Layer)

Further, the sheet 1 for the workpiece processing may be a dicing-die bonding sheet which simultaneously comprises the wafer fixing function during the dicing and the die bonding function during the die bonding.

In case the sheet 1 for the workpiece processing of the present invention is a dicing-die bonding sheet, the adhesive resin layer 3 holds the semiconductor wafer or the chip during the dicing step, and it is cut together with the wafer during the dicing, thus the adhesive resin layer 3 having the same shape as the cut chip is formed. Also, when the pickup of the chip is carried out after completing the dicing, the adhesive resin layer 3 is released from the base film 2 together with the chip. The adhesive agent layer 3 functions as the adhesive agent for fixing the chip during the die bonding. The chip with the adhesive resin layer 3 is mounted on the base, and the heating is carried out, thereby the chip and the adherend such as base or other chip or so is adhered via the adhesive resin layer 3. Here, the timing of the heating of the adhesive resin layer is not particularly limited as long as it is after mounting the chip on the base; and for example heating may be done at the same time as the mounting, or immediately after the mounting, further the adhesive resin layer may be heated during the heating step during the resin sealing which is carried out at the final step.

In case the sheet 1 for the workpiece processing of the present invention is such dicing-die bonding sheet, the adhesive layer having the pressure sensitive adhesive property and also the die bonding function is formed as the adhesive resin layer 3 on the base film 2. The adhesive resin layer 3 having such wafer fixing function and the die bonding function includes for example acrylic based adhesive agent and the epoxy adhesive agent, and depending on the needs, the energy ray curing compound and the curing auxiliary agent or so may be included as well. Also, in order to make the transfer of the adhesive resin layer 3 to the chip easier, the base film 2 of the dicing-die bonding sheet is preferably carried out with the releasing treatment. Note that, when carrying out the pickup of the adhesive resin layer 3, it is preferable to carry out the same expanding as mentioned in the above.

### (The Protection Film Forming Layer)

Further, in case the sheet 1 for the workpiece processing of the present invention is used as the sheet for forming the protection film at the backside of the chip, the adhesive resin layer 3 may be the protection film forming layer which forms the protection film at the backside of the chip. In this case, the semiconductor wafer is adhered to the protection film forming layer, and the protection film forming layer is cured to form the protection film, then the semiconductor wafer and the protection film is diced, thereby the chip with the protection film can be obtained. However, the order of the curing of the protection film forming layer and the dicing is not particularly limited. For example, the protection film forming layer may be cured before dicing, and also the protection film forming layer may be cured after the dicing. Further, the protection film forming layer may be cured during the heating step for the resin sealing carried out at the final step. Such sheet for forming the protection film comprises the resin layer with the adhesiveness (the protection film forming layer), which becomes the protection film, as the adhesive resin layer 3 on the base film 2. Also, the above mentioned adhesive agent layer may be formed on one face of the base film 2 and the protection film forming layer may be stacked on the adhesive layer. The adhesive resin layer 3 which becomes such protection film includes aforementioned acrylic based adhesive agent and the epoxy adhesive agent and the curing auxiliary agent, and depending on the needs, filler or so may be included as well.

The thickness of the adhesive resin layer 3 in the sheet 1 for the workpiece processing of the present invention varies depending on its use, in case of using as the surface protection sheet such as backside grind sheet, or as the dicing sheet or so, it is 30 to 200 μm or so. Also, in case of using as the dicing-die bonding sheet, it is 50 to 300 μm or so.

The adhesive resin layer 3 may be formed by directly coating on one face of the above mentioned base film 2, and also the adhesive resin layer 3 may be formed on the releasing film then this may be transferred onto the base film 2.

As for the method of forming the adhesive resin layer 3, the known method may be selected, and it is not particularly limited. As for such method, the adhesive resin layer forming material such as the adhesive agent or so is coated as it is which means no solvent is included, or under the condition being diluted by the solvent or emulsified condition, using the gravure coater, the Mayer bar coater, the air knife bar coater, roll coater or so. Then it is cured by setting to room temperature, or by electron beam or so, the multilayer body may be formed by a wet lamination or dry lamination, a heat melting lamination, a melt extrusion lamination, a coextrusion process Or so.

Hereinabove, the sheet for the workpiece processing of the present invention has been explained regarding the use and the representative example of the composition of the adhesive resin layer, however the adhesive resin layer of the sheet for the workpiece processing is not to be limited thereto, and the use thereof is also not to be limited thereto.

### EXAMPLE

Hereinafter, the present invention will be explained into further details based on the examples, however the present invention is not to be limited thereto. Note that, various physical properties of the examples and the comparative examples are evaluated as shown in below.

### (The Coefficient of the Static Friction)

The coefficient of the static friction was measured under below described condition in regards with the base film face of the side contacting to the casting sheet during the base film formation.

In accordance with JIS K7125. Load 200 g. Adherend: SUS #600 Contact time 1 second. Universal Testing Machine (Autograph AG-IS 500N made by Shimadzu Corporation) was used.

### (Si Element Ratio at the Casting Sheet Surface)

At the surface of the casting sheet used during the base film formation, the attached amount of 4 elements were measured under the below described condition, thereby the weight ratio of silicone (Si) with respect to the total of 4 elements attached were obtained.

Device: ESCA-3400 made by Shimadzu Corporation

Degree of vacuum: 1.0×10⁻⁶ Pa

X ray source: Mg

Discharged electric current value: 10 mA

Accelerating voltage: 10 kV

Elements measured: carbon (C), oxygen (O), nitrogen (N), silicon (Si)

### (The Broking Property)

the film obtained from the examples and comparative examples were formed into a roll form and stored at 23° C. under the environment of 50% RH, then the film was rewound thereby the presence of the blocking was verified.

### (The Processing Aptitude Evaluation)

For the processing aptitude during the backside grinding and the dicing, in case the sheet for the workpiece processing did not adhere on the table in the device during both steps, then it was good, and if it did adhere at the either step, or in case the moving error occurred, then this was determined as bad.

### (The Processing Aptitude During the Backside Grinding)

The sheet for the workpiece processing obtained in the examples and the comparative examples were adhered to the silicon wafer (the diameter of 8 inch and the thickness of 700 μm) by using the tape laminator (“RAD3510F/12” made by Lintec Corporation), then the backside of the wafer was ground until it reached 50 μm by using the grinder (“DFG8760-RAC2700F/12” made by DISCO Corporation). Then, in the same device, the lamination of the diattach film (“DF-400” made by Hitachi Chemical Co., Ltd.) was carried out to the ground wafer at the laminate temperature (130° C.×3 min, the cure temperature: 180° C.×1 min)

When the sheet for the workpiece processing did adhere on the laminate table or the grinding table in the device, or if the moving error occurred, it was evaluated as bad.

### (The Processing Aptitude During the Dicing)

At the inner peripheral part of the sheet for workpiece processing obtained from the examples and the comparative examples, the silicon wafer (the diameter of 6 inch, the thickness of 350 μm) was adhered, and at the outer peripheral part, 6 inch metal ring frame was adhered, then by using the dicing device (“DFD-651” made by DISCO Corporation), the blade dicing was carried out under the below condition to form a chip.

### (The Dicing Condition)

Device: DFD-651 made by DISCO Corporation

Chip size: 10 mm×10 mm

Cut speed: 80 mm/sec

Blade: NBC-ZH2050-27HECC made by DISCO Corporation

In case the sheet for the workpiece processing adheres to the dicing table in the device, or the moving error occurs, it was determined as the processing aptitude of the dicing was bad.

Also, as the energy ray curable resin, the polymerizable silicone compound and the adhesive resin (the adhesive agent), the below described were used.

### (The Energy Ray Curable Resin)

A: Compound (beam set 541, η=6,000 mPa·s (25° C.) made by Arakawa Chemical Industries, Ltd.) comprising 60 parts by weight of polycarbonate based urethane acrylate oligomer having the weight average molecular weight (Mw) of 6,000 with the reactive double bond functional group at the both end, 15 parts by weight of tricyclodecane acrylate, 10 parts by weight of cyclohexyl acrylate, 15 parts by weight of phenoxyethyl acrylate, and 0.5 parts by weight of 2,4,6-trimethylbenzoyl-diphenyl-phosphineoxide (Lucirin TPO, the solid portion concentration 100 wt % made by BASF)

B: Compound (beam set 543, η=5,000 mPa·s (25° C.) made by Arakawa Chemical Industries, Ltd.) comprising 60 parts by weight of polycarbonate based urethane acrylate oligomer having the weight average molecular weight (Mw) of 6,000 with the reactive double bond functional group at the both end, 20 parts by weight of isobornyl acrylate, 15 parts by weight of tetrahydrofurfuryl acrylate, 5 parts by weight of phenoxyethyl acrylate, 0.5 parts by weight of 2,4,6-trimethylbenzoyl-diphenyl-phosphineoxide (Lucirin TPO, the solid portion concentration 100 wt % made by BASF)

C: Compound (η=4,500 mPa·s (25° C.) made by Arakawa Chemical Industries, Ltd.) comprising 40 parts by weight of polyester based urethane acrylate oligomer having the weight average molecular weight (Mw) of 10,000 with the reactive double bond functional group at the both end, 40 parts by weight of isobornyl acrylate, 20 parts by weight of 2-hydroxyphenoxypropyl acrylate, 0.5 parts of 2-hydroxy-2-methyl-1-phenyl-propane-1-one (DAROCUR 1173, the solid portion concentration 100 wt % made by BASF)

D: Compound (η=4,100 mPa·s (25° C.) made by Arakawa Chemical Industries, Ltd.) comprising 60 parts by weight of polypropylene glycol based urethane acrylate oligomer having the weight average molecular weight (Mw) of 30,000 with the reactive double bond functional group at the both end, 40 parts by weight of isobornyl acrylate, and 0.5 parts by weight of 2-hydroxy-2-methyl-1-phenyl-propane-1-one (DAROCUR 1173, the solid portion concentration 100 wt % made by BASF)

### (The Polymerizable Silicone Compound)

a: Ebecryl 350 (DAICEL-ALLNEX LTD, silicone di(meth)acrylate)

b: CN9800 (ARKEMA K.K., silicone diacrylate)

c: KRM8495 (made by DAICEL-ALLNEX LTD)

d: CN990 (ARKEMA K.K., urethane modified silicone acrylate oligomer containing urethane bond in the molecule)

### (The Adhesive Resin)

The adhesive composition wherein 30 wt % toluene solution of copolymer (the weight average molecular weight MW: 700,000) comprising 84 parts by weight of butyl acrylate, 10 parts by weight of methyl methacrylate, 1 part by weight of acrylic acid, and 5 parts of 2-hydroxyethyl acrylate was mixed against 3 parts by weight of polyvalent isocyanate compound (CORONATE L (made by NIPPON POLYURETHANE INDUSTRY CO., LTD))

### Example 1

### The Energy Ray Curable Composition

The energy ray curable resin and the polymerizable silicone compound shown in Table 1 was mixed in a predetermined ratio to obtain the energy ray curable composition. The added amount of the polymerizable silicone compound in the Table shows the ratio with respect to the total 100 wt % of the energy ray curable resin and the polymerizable silicone compound.

### (The Production of the Film)

The obtained energy ray curable composition is coated on the PET film (made by TORAY INDUSTRIES, INC, Lumirror T60, PET 50 T-60 TORAY, 50 μm product) which is a casting sheet by fountain die method at 25° C. so that the thickness becomes 100 μm, thereby the energy ray curable composition layer was formed. By using belt conveyor type ultraviolet ray irradiation device (product name: ECS-401GX) made by EYE GRAPHICS CO., LTD as the ultraviolet ray irradiation device, and using the high pressure mercury lamp (high pressure mercury lamp made by EYE GRAPHICS CO., LTD, the product name: H04-L41) under the device condition of the ultraviolet ray lamp height 150 mm, the ultraviolet ray lamp output 3 kW (converted output 120 mW/cm), the illumination of the light wavelength of 365 nm is 271 mW/cm², the luminous energy of 177 mJ/cm² (the ultraviolet photometer: UV-351 made by ORC MANUFACTURING CO., LTD); thereby the ultraviolet ray irradiation was carried out. Immediately after the ultraviolet ray irradiation, the releasing film (SP-PET3801 made by Lintec Corporation) was laminated on the energy ray curable composition. Note that, the lamination was done so that the release treated face of the releasing film contacts with the energy ray curable composition. Next using the same ultraviolet ray irradiation device, and under the condition of the ultraviolet ray lamp height 150 mm, the illumination of the light wavelength of 365 nm is 271 mW/cm², the luminous energy of 600 mJ/cm² (the ultraviolet photometer: UV-351 made by ORC MANUFACTURING CO., LTD), the ultraviolet ray irradiation was carried out for twice from the laminated releasing film side; and the total luminous energy of the ultraviolet ray supplied to the energy ray curable composition layer was 1377 mJ/cm², thereby the energy ray curable composition layer was crosslinked cured.

Next, the casting sheet and the release film were released form the cured energy ray curable composition layer, thereby the film (the base film) having the thickness of 100 μm was obtained.

In regards with the base film face contacting with the casting sheet, the coefficient of the static friction was measured. Also, for the surface of the casting sheet, (the face contacting the base film), Si element ratio was measured. Also, the blocking property was evaluated. The result is shown in Table 1.

### (The Formation of the Sheet for the Workpiece Processing)

Then, the adhesive resin layer wherein the thickness is regulate to be 10 μm was adhered to the film using the laminator, thereby the sheet for the workpiece processing was obtained. The processing aptitude of the sheet for the workpiece processing was evaluated. The result is shown in Table 1.

### Examples 2 to 32 and Comparative Examples 1 to 4

The same procedure was carried out as the example 1, except for using the energy ray curable composition obtained by mixing the energy ray curable resin and the polymerizable silicone compound shown in Table 1 in a predetermined ratio. Note that, for the comparative examples, the polymerizable silicone compound was not used, and instead, the energy ray curable resin A˜D were coated and cured to obtain the base film. The result is shown in Table 1.

According to Table 1, the sheet for the workpiece processing of the examples 1 to 32 has low coefficient of the static friction, and the surface tuck property is made low, thus the blocking does not occur, and the sheet does not adhered to the table in the device or the moving error does not occur. Thus, the processing aptitude was good. Further, Si element content in the casting sheet surface was low; hence it was found that there is low possibility of the workpiece contamination such as bleed out or so of the silicone compound.

On the other hand, the sheet for the workpiece processing of the comparative example which does not include the polymerizable silicone compound has high coefficient of the static friction which is 1.0 or higher, and has surface tuck property, thus blocking took place and it had bad processing aptitude.

TABLE 1

| | | Polymerizable | | | | | |
|---|---|---|---|---|---|---|---|
| | Energy | silicone | | | | | |
| | ray | compound | | Coefficient | Si elemt ratio | | |
| | curable | | Added | of static | (%) in casting | Blocking | Processing |
| Table 1 | resin | Type | amount | friction | sheet surface | property | aptitude |
| Example 1 | A | a | 0.5 | 0.45 | 0 | None | Good |
| Example 2 | | | 1 | 0.36 | 0 | None | Good |
| Example 3 | | | 2 | 0.35 | 0 | None | Good |
| Example 4 | | | 5 | 0.4 | 0 | None | Good |
| Example 5 | | | 10 | 0.43 | 1.32 | None | Good |
| Example 6 | | b | 0.5 | 0.29 | 0.45 | None | Good |
| Example 7 | | | 1 | 0.32 | 0.18 | None | Good |
| Example 8 | | | 5 | 0.29 | 0.71 | None | Good |
| Example 9 | | | 10 | 0.32 | 2.61 | None | Good |
| Example 10 | | c | 0.5 | 0.78 | 0 | None | Good |
| Example 11 | | | 1 | 0.76 | 0 | None | Good |
| Example 12 | | | 5 | 0.49 | 0.13 | None | Good |
| Example 13 | | | 10 | 0.4 | 1.27 | None | Good |
| Example 14 | | d | 0.5 | 0.38 | 0 | None | Good |
| Example 15 | | | 1 | 0.38 | 0 | None | Good |
| Example 16 | | | 2 | 0.86 | 0.13 | None | Good |
| Example 17 | | | 5 | 0.3 | 1.57 | None | Good |
| Example 18 | B | d | 10 | 0.34 | 0.58 | None | Good |
| Example 19 | | | 0.5 | 0.307 | 0 | None | Good |
| Example 20 | | | 1 | 0.304 | 0 | None | Good |
| Example 21 | | | 2 | 0.303 | 0.18 | None | Good |
| Example 22 | | | 5 | 0.234 | 0.56 | None | Good |
| Example 23 | C | d | 0.5 | 0.63 | 0 | None | Good |
| Example 24 | | | 1 | 0.52 | 0 | None | Good |
| Example 25 | | | 2 | 0.49 | 0.12 | None | Good |
| Example 26 | | | 5 | 0.47 | 0.58 | None | Good |
| Example 27 | | | 10 | 0.43 | 0.89 | None | Good |
| Example 28 | D | d | 0.5 | 0.523 | 0 | None | Good |
| Example 29 | | | 1 | 0.435 | 0 | None | Good |
| Example 30 | | | 2 | 0.361 | 0.18 | None | Good |
| Example 31 | | | 5 | 0.284 | 0.82 | None | Good |
| Example 32 | | | 10 | 0.248 | 1.36 | None | Good |
| Comparative | A | — | — | 1.13 | 0 | Present | Bad |
| example 1 | | | | | | | |
| Comparative | B | — | — | 1.216 | 0 | None | Bad |
| example 2 | | | | | | | |
| Comparative | C | — | — | 6 or more | 0 | Present | Bad |
| example 3 | | | | | | | |
| Comparative | D | — | — | 1.122 | 0 | None | Bad |
| example 4 | | | | | | | |

### NUMERICAL REFERENCES

1: Sheet for the workpiece processing
2: Base film to be used for a sheet for the workpiece processing
3: Adhesive resin layer

1. A film made by curing a membrane comprising an energy ray curable composition including an energy ray curable resin having a viscosity at 25° C. of 100 to 5,000,000 mPa·S, and a polymerizable silicone compound.

2. The film as set forth in claim 1, wherein a weight ratio of said polymerizable silicone compound is 1.0 wt % or less.

3. The film as set forth in claim 1, wherein said polymerizable silicone compound is an organic modified polymerizable silicone compound.

4. The film as set forth in claim 3, wherein said organic modified polymerizable silicone compound is urethane modified silicone (meth)acrylate or urethane modified silicone (meth)acrylate oligomer.

5. The film as set forth in claim 1, wherein said energy ray curable resin is a mixture of urethane acrylate based oligomer and energy ray polymerizable monomer.

6. A base film to be used for a sheet for workpiece processing comprising the film as set forth in claim 1.

7. A sheet for workpiece processing comprising the base film of the claim 6 and an adhesive resin layer on at least one side of said base film.

8. The sheet for workpiece processing as set forth in claim 7, wherein said adhesive resin layer is an adhesive layer having a pressure sensitive adhesiveness.

9. The sheet for workpiece processing as set forth in claim 7, wherein said adhesive resin layer is an adhesive layer having a pressure sensitive adhesiveness and die bonding function.
